(19) United States
(12) Patent Application Publication
(10) Pub. No.: US 2010/0278206 A1
(43) Pub. Date: Nov. 4, 2010

(54) PASSIVATION OF A RESONATOR END FACE OF A SEMICONDUCTOR LASER WITH A SEMICONDUCTOR SUPERLATTICE

(76) Inventors: Karl Eberl, Berlin (DE); Nils Kirstaedter, Berlin (DE)

Correspondence Address: KF ROSS PC, 5683 RIVERDALE AVENUE, SUITE 203 BOX 900, BRONX, NY, 10471-0900, US

(21) Appl. No.: 12/747,222

(22) PCT Filed: Dec. 11, 2008
(86) PCT No.: PCT/DE08/02066

§ 371 Date: Jul. 22, 2010

(30) Foreign Application Priority Data
Dec. 11, 2007 (DE) 10 2007 059 538.9

(51) Int. Cl. H01S 5/34

(52) U.S. Cl. 372/45.012

(57) ABSTRACT

The semiconductor laser has a resonator end face (15) and a semiconductor superlattice (16) which is applied to the resonator end face (15). The semiconductor superlattice (16) acts as a passivation layer for the resonator end face (15) and has a number of layers (16.1, 16.2, 16.3, 16.3), the material compositions of which are selected in such a manner that essentially no light is absorbed at the emission wavelength of the semiconductor laser (13), the layer assembly suppresses charge carrier transport from the active layer to the surface of the outermost layer (16.4) and good lattice adaption of the semiconductor superlattice (16) to the semiconductor laser is made possible at the same time.

The present invention relates generally to the field of fabricating semiconductor lasers, particularly semiconductor lasers cleaved from a larger semiconductor crystal (bar) and thus featuring cleaved facets forming the resonator end faces of the semiconductor laser. The present invention relates more particularly in this respect to a semiconductor laser having passivated resonator end faces and a method for passivating the resonator end faces of semiconductor lasers.

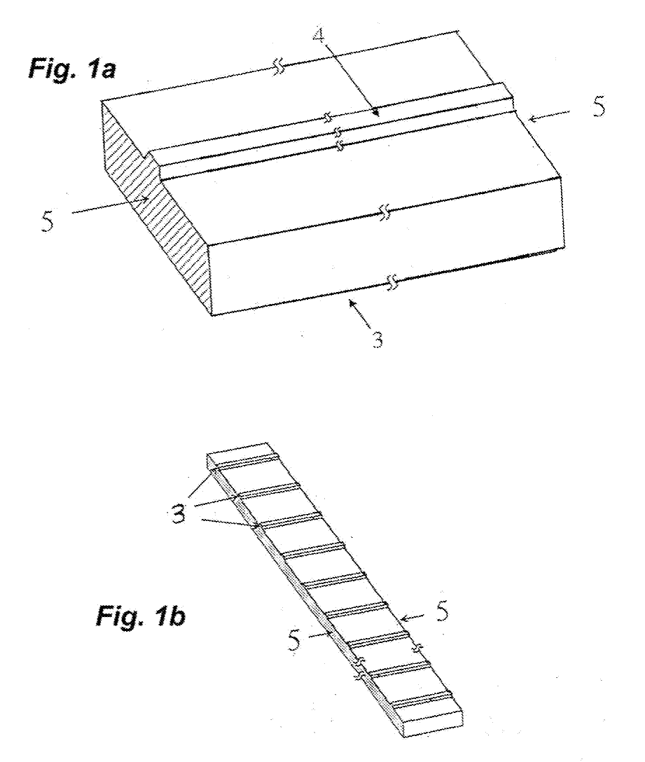

To begin with, conventional fabrication of semiconductor lasers will be detailed with reference to FIGS. 1a, 1b.

Referring now to FIG. 1a there is illustrated a single semiconductor laser shown in perspective. This semiconductor laser comprises a ridge structured waveguide 4 to achieve single-mode laser operation with high beam quality of the emitted laser beam.

Referring now to FIG. 1b there is illustrated a semiconductor stripe (laser bar) comprising a plurality of semiconductor lasers 3. It is, however, understood that the present invention is not restricted to semiconductor lasers having a ridged waveguide structure, it instead being suitably for use in principle for any kind of semiconductor laser.

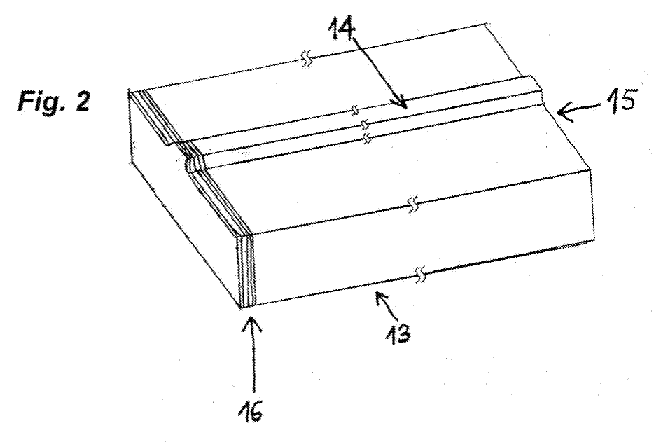

Fabrication involves substantially three steps. In a first step a laser structure is fabricated by epitaxially coating a semiconductor crystal. In a second step the laser structure is processed lithographically and provided with a contact metal. In a third step the laser mirrors are produced by cleaving the crystal along the (110) crystal axes (for polar compound semiconductors). This cleavage also defines the resonator length of the laser limited by two opposite cleavage facets 5 serving as mirrors, it also furnishing a semiconductor stripe (laser bar) comprising a plurality of laser diodes which may consist of prepatterned stripes 4 arranged juxtaposed on the laser bar (see FIG. 2a). Each of the laser diodes 3 can then be cleaved from the laser bar.

Suitably passivating the resonator end faces of the semiconductor laser significantly enhances the useful life of the semiconductor laser with high optical output performance. How passivation is effective relates back to the problem that the surface of semiconductor crystals comprise defects stemming from unsaturated surface bonds, oxides and contaminations formed in the atmosphere. In operation of the laser diode these surface defects result in absorption of the laser light from the active zone of the laser on the surface at the cleavage facet simultaneously serving as the mirror facet of the laser. This causes the mirror facet to heat up which at high optical power density triggers sudden death of the laser diode, also termed catastrophic optical mirror damage (COMD). Passivation enables the density of the surface defects to be reduced by partial saturation of the surface bonds whilst preventing oxidation and contaminations.

Existing methods of passivating resonator end faces either fail to fully achieve COMD protection or add to the optical losses in the resonator.

The object of the present invention is thus to define a semiconductor laser having enhanced life and a method for its fabrication. More particularly, the object is to totally eliminate, or at least reduce, the risk of COMD where an extremely high density of the optical light output of the semiconductor laser is involved.

This object is achieved by the features of the independent claims. Advantageous further embodiments and aspects read from the subclaims.

The invention is substantially based on a single passivation layer deposited on a resonator end face needing to satisfy the requirement that its material itself does not absorb at the laser wavelength and must thus feature a larger band gap than that of the material of the semiconductor laser. However, if it is made of a semiconductor material this means that it features as a function of the material in volume a larger lattice constant than the material of the semiconductor laser or its laser active layer. Unfortunately, as of a critical layer thickness the lattice mismatched growth of such a layer results in crystal defects at the interface and thus in absorption centers. This is why a compromise has to be found between absorption of such absorption centers and the band edge absorption of the material of the passivation layer where a single volume passivation layer is concerned, consequently making it impossible to achieve an optimum result as regards the absorption properties.

The achievement in accordance with the invention provides for depositing on the resonator end face of the semiconductor laser, instead of a single volume passivation layer, several such layers each having a layer thickness below the electronic wavelength of the charge carriers. By suitably selecting material and thickness of each layer this now makes it possible to provide a band gap which is larger than that of the semiconductor laser so that no band edge absorption exists at the emission wavelength. At the same time, the layer materials can now be selected so that the mean lattice constant of the multiple layers substantially corresponds to the lattice constant of the material of the semiconductor laser so that there is no lattice mismatch in growing the multiple layers or the layer thickness is so little that the lattice mismatch no longer results in crystal defects and thus absorption centers. The layer system as the semiconductor superlattice can now be structured from layers having a band gap alternating higher and lower. In particular, the lattice mismatch can be adjusted so that the band edge of the semiconductor material of layers within the layer packet can be increased by tension or compression.

In a first aspect the invention thus relates to a semiconductor laser including a resonator end face and a semiconductor superlattice deposited on the resonator end face.

In a second aspect the invention relates to a semiconductor laser including a resonator end face and a layer system deposited on the resonator end face, the thickness of the layers being below 20 nm, more particularly below 15 nm, especially below 10 nm, also covering all incremental values between the cited ranges (increment 1 nm). In this arrangement the layer system may comprise a sequence of layers having a band gap alternating relatively higher and lower, whereby the number of layers may be any number exceeding 2.

In a third aspect the invention relates to a semiconductor laser including a resonator end face and a layer system deposited thereon, comprising a doping ranging from more than 1×10¹⁸ cm⁻³ to below 2×10¹⁹ cm⁻³. The dopant which may be e.g. silicon, selenium, beryllium or carbon is incorporated during the epitaxial growth.

As is generally known, quantization effects occur in the semiconductor layers in a semiconductor superlattice in accordance with the first aspect and in a layer system in accordance with the second aspect, a potential well structure of individual quantized energy levels forming in a semiconductor laser having a relatively is low band gap sandwiched between two semiconductor layers having a relatively high band gap.

The semiconductor laser may be fabricated based on a III-V semiconductor material in which case layers may be incorporated in the semiconductor superlattice or layer system comprising a Inₓ₁Alₓ₂Ga₁₋ₓ₁₋ₓ₂As_{y}P_{1-y} composition with 0≦x1≦1, 0≦x2≦1 and 0≦y≦1. Selecting the parameters x1, x2 and y thus determines the stoichiometric composition of the individual layers in determining their band gaps and lattice constants. By suitably selecting a first set of parameters x1, x2 and y first layers of the semiconductor superlattice or of the layer system can be formed, each comprising a first relatively large band gap and a first lattice constant and by suitably selecting a second set of parameters x1, x2 and y second layers of the semiconductor superlattice or of the layer system can be formed, each comprising a second relatively small band gap and a second lattice constant. The parameters are to be selected so that the first band gap of the first layers is larger than the band gap of the laser active layer of the semiconductor laser and the layer thickness of the second layers is to be selected so that the spacing between the first quantization level for electrons and holes in the second layer is larger than the band gap of the laser active layer of the semiconductor laser. Satisfying these requirements results in no band edge absorption occurring in the emission wavelength of the semiconductor laser. In this arrangement the second band gap may also be smaller than the band gap of the laser active layer. In addition, the parameters may be selected so that good lattice-matching is attained. For example, an arithmetic mean of the first lattice constant of the first layers and the second lattice constant of the second layers can be substantially lattice-matched to the lattice constants of the laser active layer and their cladding layers or, for example, correspond to the lattice constant of the laser active layer or the arithmetic mean thereof and the directly adjoining cladding layers or deviate therefrom by just a predefined amount.

In this arrangement, the difference between the first band gap of the first layers and the second band gap of the second layers amounts to at least k_{B}·T=25 meV, since below this value no electronic quantization takes place in the second layers forming the potential well structures. In actual practice this difference is usually significantly higher.

It may furthermore be provided for that the layer of the semiconductor superlattice or of the layer system directly deposited on the resonator end face is one of the first layers so that this layer comprises a larger band gap than that of the laser active layer of the directly adjoining semiconductor laser. This has the advantage that at the interface to the semiconductor laser an electronic barrier for electrons and holes is formed. The level of this electronic barrier is a function of the difference between the band gap of the laser active layer of the semiconductor laser and the first band gap of the first layers and the thickness of the electronic barrier depends on the layer thickness of this layer. The electronic barrier can prevent charge carriers gaining access from the semiconductor laser to the surface of the outermost layer of the semiconductor superlattice or of the layer system and recombining there nonradiatively.

It may furthermore be provided for that the semiconductor superlattice or the layer system incorporates an outermost layer comprising a InₓGa₁₋ₓAs_{y}P_{1-y} composition with 0≦x≦1, 0≦y≦1. This composition is selected to include no aluminum since materials compounded with aluminum are known to easily oxidize and thus comprise a high density of surface absorption centers, preventing, or at least hampering, surface recombination of charge carriers.

The invention will now be detailed by way of a sole example embodiment as shown in the drawing in which

FIGS. 1a, b is a diagrammatic view in perspective of a semiconductor laser (a) and a semiconductor stripe (b), respectively;

FIG. 2 is a diagrammatic view in perspective of one embodiment of a semiconductor laser in accordance with the invention;

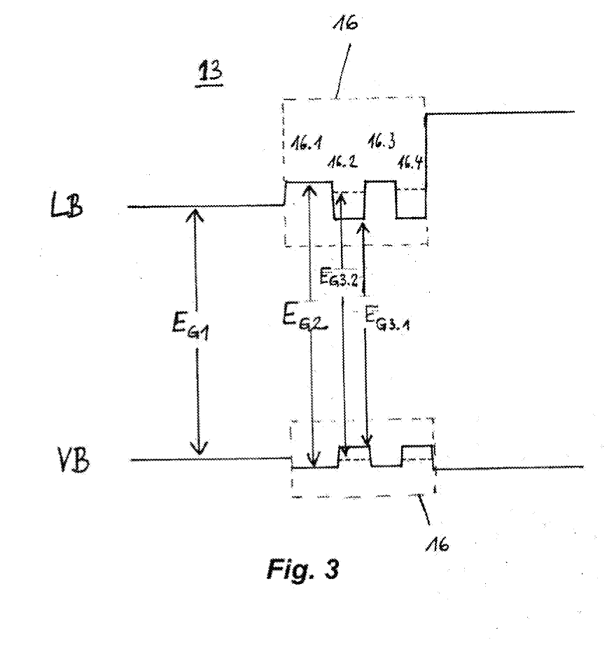

FIG. 3 is a diagrammatic view of an electronic band structure of a further example embodiment of a semiconductor laser in accordance with the invention;

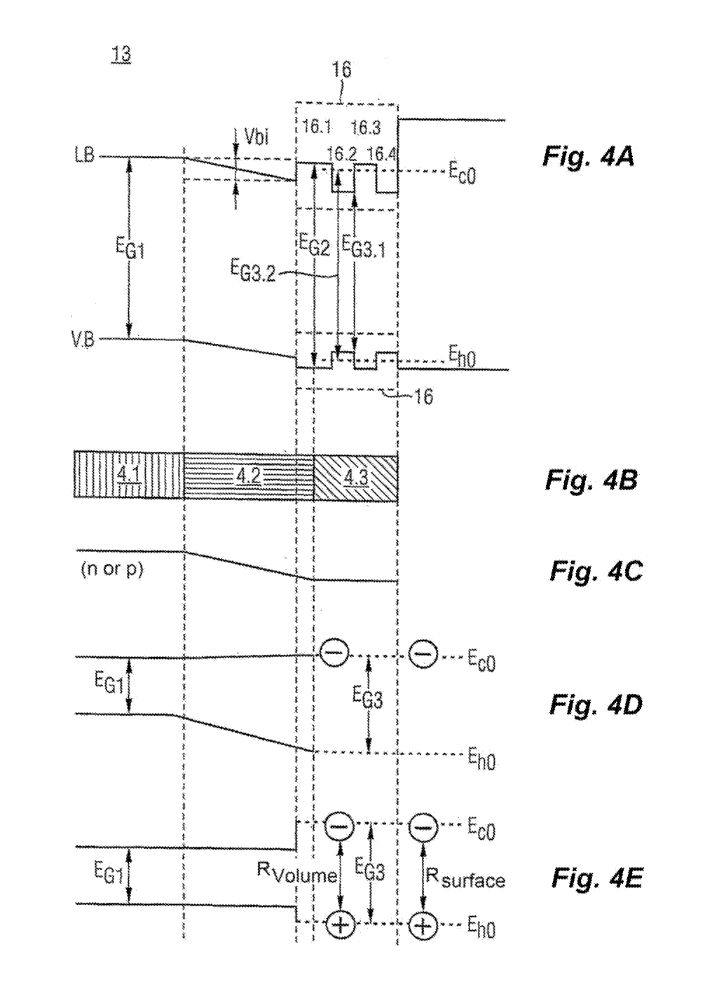

FIG. 4A is a diagrammatic view of the electronic band structure with doping of the passivation layer of the semiconductor laser in accordance with the invention;

FIG. 4B is a diagrammatic view of the depletion zone with doping of the passivation layer of the semiconductor laser in accordance with the invention;

FIG. 4C is a diagrammatic view of the charge carrier concentration with doping of the passivation layer of the semiconductor laser in accordance with the invention;

FIG. 4D is a diagrammatic view of the recombination channels with doping of the passivation layer of the semiconductor laser in accordance with the invention;

FIG. 4E is a diagrammatic view of the recombination channels without doping of the passivation layer of the semiconductor laser in accordance with the invention.

Referring now to FIG. 2 there is illustrated a diagrammatic view in perspective of an example embodiment for a semiconductor laser in accordance with the invention. The structure of the semiconductor laser 13 is substantially the same as that as already explained at the outset in conjunction with FIG. 1a. The semiconductor laser 13 thus comprises a ridge structured waveguide 14 but is not restricted thereto. The semiconductor laser 13 comprises furthermore resonator end faces 15, of which only the resonator end face on the right-hand side is identified by a corresponding reference numeral. The opposite resonator end face on the left-hand side is provided with a layer system 16 deposited on the resonator end face as a passivation layer. It is understood that the same or similar layer system can also be deposited on the resonator end face 15 on the right-hand side.

The layer system 16 is in particular a semiconductor superlattice comprising in the example embodiment four layers. These four semiconductor layers may be deposited epitaxially, is particularly by molecular beam epitaxy, on the resonator end face.

The semiconductor laser 13 can be structured based on a III-V material system, particularly based on GaAs or AlGaAs. The layer system 16 may comprise layers comprising a Inₓ₁Alₓ₂Ga₁₋ₓ₁₋ₓ₂As_{y}P_{1-y} composition with 0≦x1≦1, 0≦x2≦1 and 0≦y≦1. The layers may incorporate first layers having a relatively large band gap, larger than the band gap of the laser active layer of the semiconductor laser 13 and second layers having a second band gap smaller than the band gap of the first layers. The layer thicknesses of both the first and second layers are below 20 nm, preferably below 15 nm, preferably below 10 nm so that the second layers form potential well structures in which quantization energy levels are provided for electrons and holes.

Since, for example, the band gap of the first layers is larger than the band gap of the semiconductor laser 13 or of the laser active layer of the semiconductor laser 13 and the band gap between the first quantization level for electrons and holes of the second layers is larger than the band gap of the semiconductor laser 13 or of the laser active layer of the semiconductor laser 13 no band edge absorption occurs at the emission wavelength of the semiconductor laser 13. At the same time, however, the materials of the first and second layers may be selected so that the mean lattice constant of the materials of the first and second layers corresponds to the lattice constant of the material of the semiconductor laser 13 or to a mean lattice constant of the laser active layer and the cladding layers so that the passivation layer is lattice-matched to the semiconductor laser. The parameters x1, x2 and y can be suitably selected to satisfy the above requirements.

In this arrangement the outermost epitaxial layer, i.e. the last grown layer of the layer system may be typically a layer comprising a InₓGa₁₋ₓAs_{y}P_{1-y} composition with 0≦x≦1, 0≦y≦1 so that no aluminum is contained in the outermost layer since this is known to comprise a high density of the surface absorption centers.

The epitaxial layer grown directly on the resonator end face may comprise, for example, one of the layers defined first in the layer system and thus feature a larger band gap than that of the semiconductor material of the semiconductor laser 13 or its laser active layer. In addition, this first layer may be somewhat thicker than the other layers. Both of these factors together result in an adequate electronic barrier for electrons and holes to prevent charge carriers gaining access from the semiconductor laser to the layer system or even to the outermost layer of the layer system.

Referring now to FIG. 3 there is illustrated a conduction and valence band structure of a further example embodiment of a semiconductor laser in accordance with the invention, the upper half of the FIG. showing the conduction band profile whilst the lower half shows the valence band profile. Both profiles are plotted over a space coordinate oriented perpendicular to the plane of the layers to thus distinguish three different zones, the partial zone on the left incorporating the semiconductor laser 13, the band structure in this case relating to the laser active layer of the semiconductor laser 13. The band gap in this zone is referenced EG1. Incorporated in the partial zone on the right is air, here in this case the corresponding vacuum levels of the conduction and valence band are indicated. Incorporated in middle partial zone is the (passivation) layer system 16 which in the present example embodiment comprises four partial zones featuring differing band gaps and differing lattice constants. Two first layers 16.1 and 16.3 comprise a first band gap EG2 which is larger than the band gap EG1 of the laser active layer, whereas two second layers 16.2 and 16.4 comprise a composition featuring a band gap EG3.1 which in the present example embodiment is smaller than the band gap EG1 of the laser active layer. But since the second layers 16.2 and 16.4 are configured by the given structure of a semiconductor superlattice as potential well structures, electrons and holes in these layers can only assume certain quantization levels, indicated in FIG. 3 as broken lines. In the present case only one quantization level exists in each case and the energy gap between the quantization level is referenced EG3.2 which is larger than the band gap EG1 of the laser active layer.

The thickness of the layers may be selected, for example, such that the thickness of layer 16.1 is 3 nm, that of layer 16.2 is 3 nm, that of layer 16.3 is 3 nm and that of layer 16.4 is also 3 nm, it being, of course, possible that more than 4 layers may be involved in the layer system.

The layer 16.1 thus forms a barrier for electrons and holes to prevent them from gaining access from the laser active layer to the layer system 16 where they could recombine at the surface of the outermost layer 16.4 and thus nonradiatively heat up the layer, which in turn could reduce the band edge down to absorption of the laser light.

The materials of the example embodiment as shown in FIG. 3 can be selected corresponding to those as recited for the example embodiment as shown in FIG. 2, i.e. the material composition of the first layers 16.1 and 16.3 may be identical, likewise the second layers 16.2 and 16.4 having an identical material composition. The parameters x1, x2 and y then need to be selected so that the energy gaps EG2 and EG3.1 are larger than the energy gap EG1 of the laser active layer. The difference between the energy gaps EG2 and EG3.1 must amount to at least 25 meV so that quantization levels are provided in the second layers 16.2 and 16.4. However, it is understood that unlike the example embodiment as shown, the energy gap EG3.1 may also be larger than the energy gap EG1.

The outermost layer 16.4 may comprise a material composition other than that of layer 16.2. More particularly, it may be configured as a layer incorporating no aluminum and comprise the InₓGa₁₋ₓAs_{y}P_{1-y} composition with 0≦x≦1, 0≦y≦1 to ensure that substantially no surface absorption centers can form from aluminum.

Referring now to FIGS. 4A-E there are illustrated diagram representing a further example embodiment of a semiconductor laser in accordance with the invention. The passivation layer 4.3 (FIG. 4b) is adequately doped so that an electric potential V_{bi} (see FIG. 4a) forms over a depletion zone 4.2 (see FIG. 4b) between the passivation layer and the laser layer system 4.1 (see FIG. 4b), particularly also between the laser active layer of the laser. Doping is adjusted so that the charge carrier concentration (see FIG. 4c) of electrons and holes in the passivation layer is negligible as compared to the concentration of the majority charge carriers, resulting in, as shown in FIGS. 4C-E a reduction in the recombination (Rᵥₒₗ) of holes and electrons in the passivation layers 16.1-16.3 (see FIG. 4a) and particularly at the interface (R_{surface}) 16.4. Furthermore, the free charge carrier absorption of electrons or holes by photons of the laser active layer, which is proportional to their charge carrier concentration, can be adjusted by doping. The free charge carrier absorption for electrons in the III-V material is typically smaller by a factor of 4. Doping can be adjusted within the limits of 1×10¹⁸ cm⁻³ and 2×10¹⁹ cm⁻³ so that the epitaxial perfection of the semiconductor superlattice remains intact. Reducing the recombination and free charge carrier absorption by nonradiative processes diminishes heating up of the passivation layer in thus elevating the threshold of their destruction when exposed to high injection currents and high photon densities.

1-21. (canceled)

22. A semiconductor laser including a resonator end face and a semiconductor superlattice deposited on the resonator end face fabricated based on III-V semiconductor material and incorporating layers each comprising a Inₓ₁Alₓ₂Ga₁₋ₓ₁₋ₓ₂AS_{y}P_{1-y} composition with 0<x1<1, 0<x2<1 and 0<y<1 and an outermost layer comprising a InₓGa₁₋ₓAs_{y}P_{1-y} composition with 0<x<1, 0<y<1, the semiconductor superlattice incorporating first layers having a first band gap and second layers having a second band gap, the first band gap being larger than the band gap of the material of the semiconductor laser, the first layers comprising a first lattice constant and the second layers a second lattice constant and the arithmetic mean of the first and second lattice constants corresponding to the lattice constant of the laser active layer of the semiconductor laser or a lattice constant derived therefrom or differs therefrom merely by a predefined maximum amount.

23. The semiconductor laser as set forth in claim 22, wherein the superlattice deposited on the resonator end face incorporating layers, each comprising a thickness below 20 nm, more particularly below 15 nm, especially below 10 nm.

24. The semiconductor laser as set forth in claim 22, wherein the layer of the semiconductor superlattice directly deposited on the resonator end face is one of the first layers and, where necessary, comprises a larger layer thickness than that of the other layers.

25. The semiconductor laser as set forth in claim 22, wherein the semiconductor superlattice is n- or p-doped such that a depletion zone having an electric potential is configured adjoining the semiconductor superlattice and the doping concentration ranges from 1×10¹⁸ cm⁻³ to 2×10¹⁹ cm⁻³.
